(19) United States
(12) Patent Application Publication
(10) Pub. No.: US 2026/0371848 A1
(43) Pub. Date: Nov. 19, 2026

(54) DISPLAY DEVICE AND MANUFACTURING METHOD OF THE SAME

(71) Applicant: Japan Display Inc., Tokyo (JP)

(72) Inventors: Hayata AOKI, Tokyo (JP); Takaya TAMARU, Tokyo (JP)

(73) Assignee: Japan Display Inc., Tokyo (JP)

(21) Appl. No.: 19/676,846

(22) Filed: May 14, 2026

(30) Foreign Application Priority Data
May 15, 2025 (JP) 2025-081858

(51) Int. Cl. H10K 59/121; H10D 86/40; H10D 86/60; H10K 59/12; H10K 59/122

(52) U.S. Cl. CPC H10K 59/1213; H10D 86/471; H10D 86/60; H10K 59/1201; H10K 59/122

(57) ABSTRACT

According to one embodiment, a display device includes a first thin-film transistor, an organic insulating layer above the first thin-film transistor, a second thin-film transistor including a semiconductor layer, a gate electrode, and a gate insulating layer between the semiconductor layer and the gate electrode, an inorganic insulating layer above the second thin-film transistor, and a display element located above the inorganic insulating layer and driven by a pixel circuit including the first and second thin-film transistors. The gate insulating layer includes a through-hole reaching the organic insulating layer. The inorganic insulating layer closes the through-hole.

### CROSS-REFERENCE TO RELATED APPLICATIONS

This application is based upon and claims the benefit of priority from Japanese Patent Application No. 2025-081858, filed May 15, 2025, the entire contents of which are incorporated herein by reference.

### FIELD

Embodiments described herein relate generally to a display device and a manufacturing method of the same.

### BACKGROUND

To achieve higher definition, a display device may employ a configuration in which a plurality of thin-film transistors (TFT) that drive pixels are arranged in two layers in the thickness direction of the substrate. Furthermore, to reduce a step caused by the thin-film transistors in the lower layer, a display device may include an insulating layer for planarization between the thin-film transistors in the lower layer and the thin-film transistors in the upper layer.

In this type of display devices, a technique for improving the yield is required. For example, from the viewpoint of improving flatness of a base of the thin-film transistors in the upper layer, the insulating layer is preferably formed of an organic insulating material. However, an organic insulating material generally has a low heat-resistance temperature. Thus, heat generated during formation of the thin-film transistors in the upper layer may cause defects such as bubble generation and stripping in the insulating layer.

### BRIEF DESCRIPTION OF THE DRAWINGS

FIG. 1 is a view showing a configuration example of a display device according to an embodiment.

FIG. 2 is a schematic plan view showing an example of the layout of subpixels.

FIG. 3 is a schematic cross-sectional view of the display device along III-III line of FIG. 2.

FIG. 4 is a schematic cross-sectional view showing a configuration applicable to a circuit layer.

FIG. 5 is a schematic cross-sectional view showing an area in the vicinity of a through-hole in an enlarged manner.

FIG. 6 is a flowchart showing an example of a manufacturing method of the display device of the embodiment.

FIG. 7A is a schematic cross-sectional view showing a manufacturing process of a thin-film transistor in an upper layer.

FIG. 7B is a schematic cross-sectional view showing a process following the one shown in FIG. 7A.

FIG. 7C is a schematic cross-sectional view showing a process following the one shown in FIG. 7B.

FIG. 7D is a schematic cross-sectional view showing a process following the one shown in FIG. 7C.

FIG. 7E is a schematic cross-sectional view showing a process following the one shown in FIG. 7D.

FIG. 7F is a schematic cross-sectional view showing a process following the one shown in FIG. 7E.

FIG. 7G is a schematic cross-sectional view showing a process following the one shown in FIG. 7F.

FIG. 7H is a schematic cross-sectional view showing a process following the one shown in FIG. 7G.

FIG. 7I is a schematic cross-sectional view showing a process following the one shown in FIG. 7H.

FIG. 8 is a flowchart showing a flow of a process for forming inorganic insulating layers.

### DETAILED DESCRIPTION

In general, according to one embodiment, a display device includes a first thin-film transistor, an organic insulating layer located above the first thin-film transistor, a second thin-film transistor located above the organic insulating layer and including a semiconductor layer, a gate electrode facing the semiconductor layer, and a gate insulating layer located between the semiconductor layer and the gate electrode, an inorganic insulating layer located above the second thin-film transistor, and a display element located above the inorganic insulating layer and driven by a pixel circuit including the first thin-film transistor and the second thin-film transistor. The gate insulating layer includes a through-hole reaching the organic insulating layer. The inorganic insulating layer closes the through-hole.

According to one embodiment, a method of manufacturing a display device includes forming a first thin-film transistor, forming an organic insulating layer above the first thin-film transistor, forming, above the organic insulating layer, a second thin-film transistor including a semiconductor layer, a gate electrode facing the semiconductor layer, and a gate insulating layer located between the semiconductor layer and the gate electrode and having a through-hole reaching the organic insulating layer, heating a substrate on which the first thin-film transistor, the organic insulating layer, and the second thin-film transistor are formed, forming, after the heating, an inorganic insulating layer located above the second thin-film transistor and closing the through-hole, and forming, above the inorganic insulating layer, a display element driven by a pixel circuit including the first thin-film transistor and the second thin-film transistor.

For example, the embodiments can improve the yield of a display device.

One embodiment will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc. of the respective parts are schematically illustrated in the drawings, compared to the actual modes. However, the schematic illustration is merely an example, and adds no restrictions to the interpretation of the invention. In addition, in the specification and drawings, structural elements which function in the same or a similar manner to those described in connection with preceding drawings are denoted by like reference numbers, detailed description thereof being omitted unless necessary.

In the figures, an X-axis, a Y-axis, and a Z-axis orthogonal to each other are described to facilitate understanding as needed. A direction parallel to the X-axis is referred to as an X-direction. A direction parallel to the Y-axis is referred to as a Y-direction. A direction parallel to the Z-axis is referred to as a Z-direction. The Z-direction is the normal direction of a plane including the X-direction and the Y-direction. When various elements are viewed parallel to the Z-direction, the appearance is defined as a plan view.

The present embodiment discloses a display device including an organic electroluminescence element as an example of the display device. However, the present embodiment does not preclude application of the individual technical concepts disclosed in the present embodiment to other types of display devices.

For example, at least part of the configuration disclosed in the present embodiment is applicable to a display device comprising a liquid crystal display element, a display device comprising an LED element, an electronic paper-type display device having an electrophoretic element, a display device applying Micro Electro Mechanical Systems (MEMS), or a display device applying electrochromism.

The display device of the present embodiment could be mounted on various types of electronic devices such as a television, a personal computer, a vehicle-mounted device, a tablet, a smartphone, a mobile phone, and a wearable terminal.

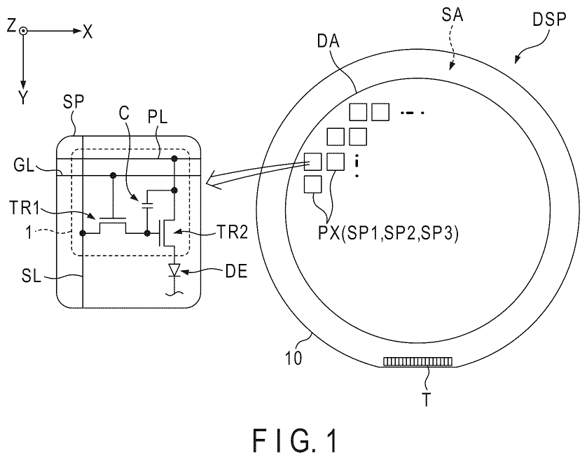

FIG. 1 is a view showing a configuration example of a display device DSP according to the present embodiment. The display device DSP comprises an insulating substrate 10. The substrate 10 has a display area DA for displaying images and a surrounding area SA around the display area DA. The substrate 10 may be glass or a resinous film having flexibility.

In the present embodiment, the substrate 10 and the display area DA each have a circular shape in plan view. The shape of each of the substrate 10 and the display area DA in plan view is not limited to a circular shape and may be another shape such as a rectangular shape, a square shape, or an elliptic shape.

The display area DA comprises a plurality of pixels PX arranged in a matrix in the X-direction and the Y-direction. Each pixel PX includes a plurality of subpixels SP which display different colors. The present embodiment assumes a case where each pixel PX includes a blue subpixel SP1, a green subpixel SP2, and a red subpixel SP3. Each pixel PX may include a subpixel SP that exhibits another color such as white in addition to the subpixels SP1, SP2, and SP3 or instead of one of the subpixels SP1, SP2, and SP3.

The display device DSP further comprises a terminal portion T to which signals and voltages for driving the subpixels SP1, SP2, and SP3 are input. The terminal portion T is provided in the surrounding area SA. For example, a flexible printed circuit board, which applies the voltages and signals, is connected to the terminal portion T.

The subpixel SP comprises a pixel circuit 1 and a display element DE driven by the pixel circuit 1. The pixel circuit 1 comprises a thin-film transistor TR1 (the first thin-film transistor), a thin-film transistor TR2 (the second thin-film transistor), and a capacitor C.

A plurality of scanning lines GL supplying a scanning signal to the pixel circuit 1 of each subpixel SP, a plurality of signal lines SL supplying a video signal to the pixel circuit 1 of each subpixel SP, and a plurality of power lines PL are provided in the display area DA. In the example of FIG. 1, the scanning lines GL and the power lines PL extend in the X-direction, and the signal lines SL extend in the Y-direction.

A gate electrode of the thin-film transistor TR1 is connected to the scanning line GL. A source electrode of the thin-film transistor TR1 is connected to the signal line SL, and a drain electrode of the thin-film transistor TR1 is connected to a gate electrode of the thin-film transistor TR2 and to the capacitor C. A source electrode of the thin-film transistor TR2 is connected to the power line PL and to a capacitor C, and a drain electrode of the thin-film transistor TR2 is connected to the display element DE.

The configuration of the pixel circuit 1 is not limited to the illustrated example. For example, the pixel circuit 1 may comprise more thin-film transistors and capacitors.

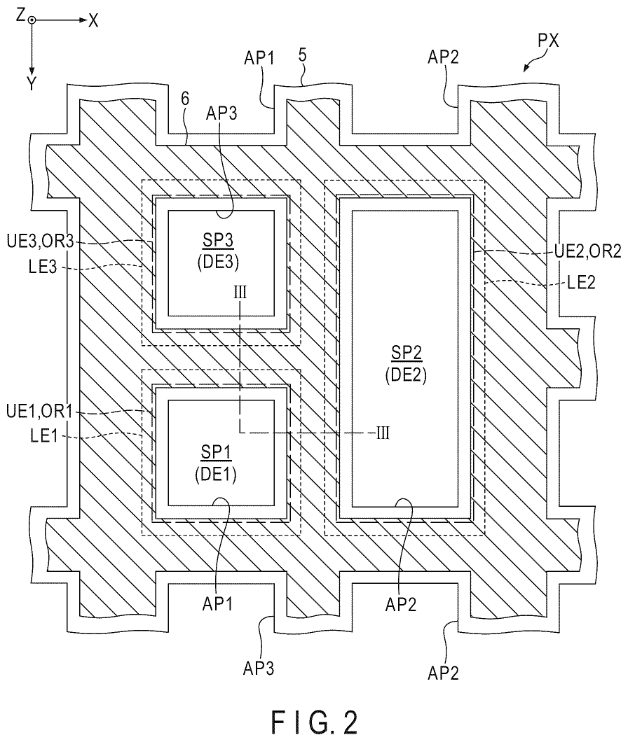

FIG. 2 is a schematic plan view showing an example of the layout of the subpixels SP1, SP2, and SP3 constituting one pixel PX. In the example of FIG. 2, the subpixels SP1 and SP3 are arranged in the Y-direction. Each of the subpixels SP1 and SP3 is adjacent to the subpixel SP2 in the X-direction.

When the subpixels SP1, SP2, and SP3 are arranged in this layout, in the display area DA, a column in which the subpixels SP1 and SP3 are alternately arranged in the Y-direction and a column in which the plurality of subpixels SP2 are repeatedly arranged in the Y-direction are formed. These columns are alternately arranged in the X-direction. The layout of the subpixels SP1, SP2, and SP3 is not limited to the example of FIG. 2.

A rib layer 5 is provided in the display area DA. The rib layer 5 has pixel apertures AP1, AP2, and AP3 in the respective subpixels SP1, SP2, and SP3. In the example of FIG. 2, the pixel apertures AP1 and AP3 are rectangles having the same planar size. In contrast, the pixel aperture AP2 is a rectangle extending longer in the Y-direction than the pixel apertures AP1 and AP3. The shapes of the pixel aperture AP1, AP2, and AP3 are not limited to this example.

The subpixel SP1 comprises a lower electrode LE1, an upper electrode UE1, and an organic layer OR1, which overlap the pixel aperture AP1. The subpixel SP2 comprises a lower electrode LE2, an upper electrode UE2, and an organic layer OR2, which overlap the pixel aperture AP2. The subpixel SP3 comprises a lower electrode LE3, an upper electrode UE3, and an organic layer OR3, which overlap the pixel aperture AP3.

Parts overlapping the pixel aperture AP1 of the lower electrode LE1, the upper electrode UE1, and the organic layer OR1 constitute a display element DE1 of the subpixel SP1. Parts overlapping the pixel aperture AP2 of the lower electrode LE2, the upper electrode UE2, and the organic layer OR2 constitute a display element DE2 of the subpixel SP2. Parts overlapping the pixel aperture AP3 of the lower electrode LE3, the upper electrode UE3, and the organic layer OR3 constitute a display element DE3 of the subpixel SP3. Each of the display elements DE1, DE2, and DE3 may further include a cap layer to be described later. The rib layer 5 surrounds each of the display elements DE1, DE2, and DE3.

The lower electrodes LE1, LE2, and LE3 correspond to the first electrode of the respective display elements DE1, DE2, and DE3. The upper electrodes UE1, UE2, and UE3 correspond to the second electrode of the respective display elements DE1, DE2, and DE3.

A conductive partition 6 is provided above the rib layer 5. The partition 6 functions as lines applying common voltage to the upper electrodes UE1, UE2, and UE3. The partition 6 entirely overlaps the rib layer 5 and has the same planar shape as the rib layer 5. Further, the partition 6 surrounds each of the pixel apertures AP1, AP2, and AP3.

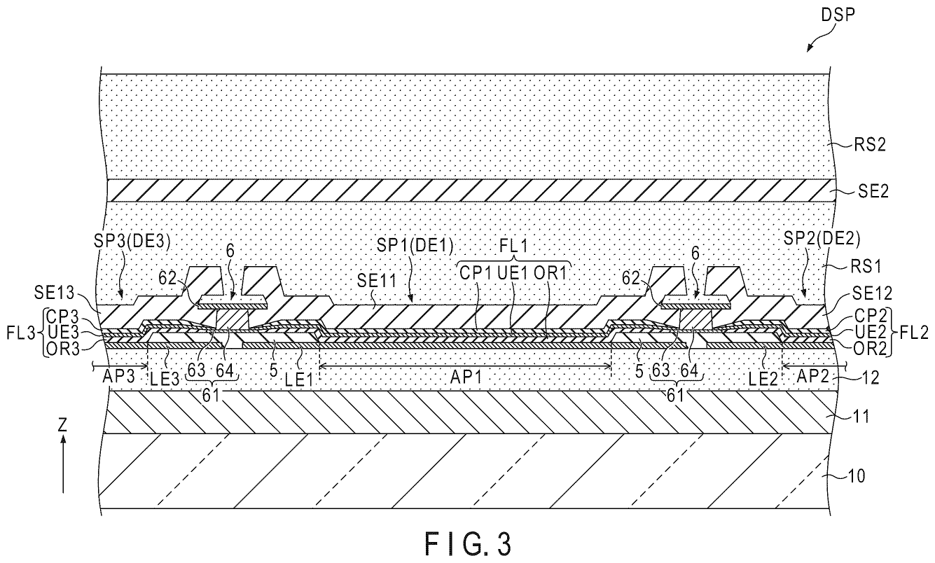

FIG. 3 is a schematic cross-sectional view of the display device DSP along the line III-III in FIG. 2. A circuit layer 11 is provided on the substrate 10 described above. The circuit layer 11 includes various circuits and lines such as the pixel circuit 1, the scanning lines GL, the signal lines SL, and the power lines PL shown in FIG. 1. The circuit layer 11 is covered with an organic insulating layer 12. The organic insulating layer 12 functions as a planarization film, which planarizes irregularities formed by the circuit layer 11.

The lower electrodes LE1, LE2, and LE3 are provided on the organic insulating layer 12. The rib layer 5 is provided on the organic insulating layer 12 and the lower electrodes LE1, LE2, and LE3. End portions of the lower electrodes LE1, LE2, and LE3 are covered with the rib layer 5. Although not shown in the section of FIG. 3, the lower electrodes LE1, LE2 and LE3 are connected to the respective pixel circuits 1 of the circuit layer 11 through respective contact holes provided in the organic insulating layer 12.

The partition 6 includes a conductive lower portion 61 provided on the rib layer 5 and an upper portion 62 provided on the lower portion 61. The upper portion 62 has the width greater than the width of the lower portion 61. That is, the partition 6 has an overhang shape in which both end portions of the upper portion 62 protrude relative to the side surfaces of the lower portion 61.

In the example of FIG. 3, the lower portion 61 has a bottom layer 63 provided on the rib layer 5, and a stem layer 64 provided on the bottom layer 63. For example, the bottom layer 63 is formed to be thinner than the stem layer 64. In the example of FIG. 3, both end portions of the bottom layer 63 protrude relative to the side surfaces of the stem layer 64.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2, and UE3 contact the lower portion 61 of the partition 6.

The display element DE1 includes a cap layer CP1 covering the upper electrode UE1. The display element DE2 includes a cap layer CP2 covering the upper electrode UE2. The display element DE3 includes a cap layer CP3 covering the upper electrode UE3. The cap layers CP1, CP2, and CP3 function as optical adjustment layers which improve the extraction efficiency of the light emitted from the organic layers OR1, OR2, and OR3, respectively.

In the following explanation, a multilayer body including the organic layer OR1, the upper electrode UE1, and the cap layer CP1 is called a stacked film FL1. A multilayer body including the organic layer OR2, the upper electrode UE2, and the cap layer CP2 is called a stacked film FL2. A multilayer body including the organic layer OR3, the upper electrode UE3, and the cap layer CP3 is called a stacked film FL3.

Sealing layers SE11, SE12 and SE13 are provided in the respective subpixels SP1, SP2 and SP3. The sealing layer SE11 continuously covers the display element DE1 and the partition 6 around the display element DE1. The sealing layer SE12 continuously covers the display element DE2 and the partition 6 around the display element DE2. The sealing layer SE13 continuously covers the display element DE3 and the partition 6 around the display element DE3.

In the example of FIG. 3, the end portions of the sealing layers SE11, SE12, and SE13 are located above the partition 6 and are spaced apart from each other. These end portions may overlap each other in the Z-direction above the partition 6.

For example, gaps are formed between the respective sealing layers SE11, SE12, and SE13 and the upper portion 62 of the partition 6. The stacked films FL1, FL2, and FL3 may be provided in at least part of these gaps.

The sealing layers SE11, SE12, and SE13 are covered with a resin layer RS1. The resin layer RS1 is covered with the sealing layer SE2. The sealing layer SE2 is covered with a resin layer RS2. The resin layers RS1 and RS2 and the sealing layer SE2 are continuously provided in at least the entire display area DA and partly extend in the surrounding area SA as well.

The display device DSP may comprise a detection electrode for detecting user's operation. The detection electrode may be provided, for example, on the sealing layer SE2. Further, a cover member such as a polarizer, a protective film, and a cover glass may be further provided above the resin layer RS2. This cover member may be attached to the resin layer RS2 via, for example, an adhesive layer such as an optical clear adhesive (OCA).

The organic insulating layer 12 is formed of an organic insulating material such as a polyimide. Each of the rib layer 5 and the sealing layers SE11, SE12, SE13, and SE2 is formed of an inorganic insulating material such as a silicon nitride (SiNx), a silicon oxide (SiOx), or a silicon oxynitride (SiON). In one example, the rib layer 5 is formed of a silicon oxynitride, and each of the sealing layers SE11, SE12, SE13, and SE2 is formed of a silicon nitride. Each of the resin layers RS1 and RS2 is formed of, for example, a resinous material such as an epoxy resin or an acrylic resin.

Each of the lower electrodes LE1, LE2, and LE3 has a reflective layer formed of, for example, silver, and a pair of conductive oxide layers covering the upper and lower surfaces of the reflective layer. Each of the conductive oxide layers can be formed of, for example, a transparent conductive oxide such as an indium tin oxide (ITO), an indium zinc oxide (IZO), or an indium gallium zinc oxide (IGZO).

The upper electrodes UE1, UE2, and UE3 are formed of, for example, a metal material such as an alloy of magnesium and silver (MgAg). For example, the lower electrodes LE1, LE2, and LE3 correspond to anodes, and the upper electrodes UE1, UE2, and UE3 correspond to cathodes.

Each of the organic layers OR1, OR2, and OR3 is formed of a plurality of thin films including a light emitting layer. In one example, the organic layers OR1, OR2, and OR3 have a structure in which a hole-injection layer, a hole-transport layer, an electron blocking layer, a light emitting layer, a hole blocking layer, an electron-transport layer, and an electron-injection layer are stacked in this order in the Z-direction. The organic layers OR1, OR2, and, OR3 each may have other structures such as a tandem structure including a plurality of light emitting layers.

Each of the cap layers CP1, CP2, and CP3 comprises, for example, a multilayer structure in which a plurality of transparent layers are stacked. These transparent layers may include a layer formed of an inorganic material and a layer formed of an organic material. The transparent layers have refractive indexes different from each other. For example, the refractive indexes of these transparent layers are different from the refractive indexes of the upper electrodes UE1, UE2, and UE3 and the refractive indexes of the sealing layers SE11, SE12, and SE13. At least one of the cap layers CP1, CP2, and CP3 may be omitted.

For example, each of the bottom layer 63 and the stem layer 64 of the partition 6 is formed, for example, of a metal material. For the metal material of the bottom layer 63, for example, molybdenum, titanium, a titanium nitride (TiN), a molybdenum-tungsten alloy (MoW), or a molybdenum-niobium alloy (MoNb) can be used. For the metal material of the stem layer 64, for example, aluminum, an aluminum-neodymium alloy (AlNd), an aluminum-yttrium alloy (AlY), or an aluminum-silicon alloy (AlSi) can be used. The stem layer 64 may be formed of an insulating material.

For example, the upper portion 62 of the partition 6 includes a lower layer formed of a metal material and an upper layer formed of a conductive oxide. In this case, for the metal material of the lower layer, titanium, a titanium nitride, molybdenum, tungsten, a molybdenum-tungsten alloy, or a molybdenum-niobium alloy may be used. Further, for a conductive oxide of the upper layer, an ITO or an IZO may be used. The upper portion 62 may comprise three or more layers or may consist of a single layer. The upper portion 62 may further include a layer formed of an insulating material.

The partition 6 is supplied with common voltage. This common voltage is applied to each of the upper electrodes UE1, UE2, and UE3 in contact with the lower portion 61. Pixel voltages according to the video signals of the signal lines SL are applied to the lower electrodes LE1, LE2, and LE3 through the respective pixel circuits 1 provided in the subpixels SP1, SP2, and SP3.

The organic layers OR1, OR2, and OR3 emit light in response to the application of a voltage. Specifically, when a potential difference is formed between the lower electrode LE1 and the upper electrode UE1, the light emitting layer of the organic layer OR1 emits light in a blue wavelength range. When a potential difference is formed between the lower electrode LE2 and the upper electrode UE2, the light emitting layer of the organic layer OR2 emits light in a green wavelength range. When a potential difference is formed between the lower electrode LE3 and the upper electrode UE3, the light emitting layer of the organic layer OR3 emits light in a red wavelength range.

As another example, the light emitting layers of the organic layers OR1, OR2, and OR3 may emit light of the same color (for example, white). In this case, the display device DSP may comprise a color filter that converts light emitted from the light emitting layers into light of the colors corresponding to those of the subpixels SP1, SP2, and SP3. In addition, the display device DSP may comprise a layer including quantum dots that are excited by the light emitted from the light emitting layers to generate the light of the colors corresponding to those of the subpixels SP1, SP2, and SP3.

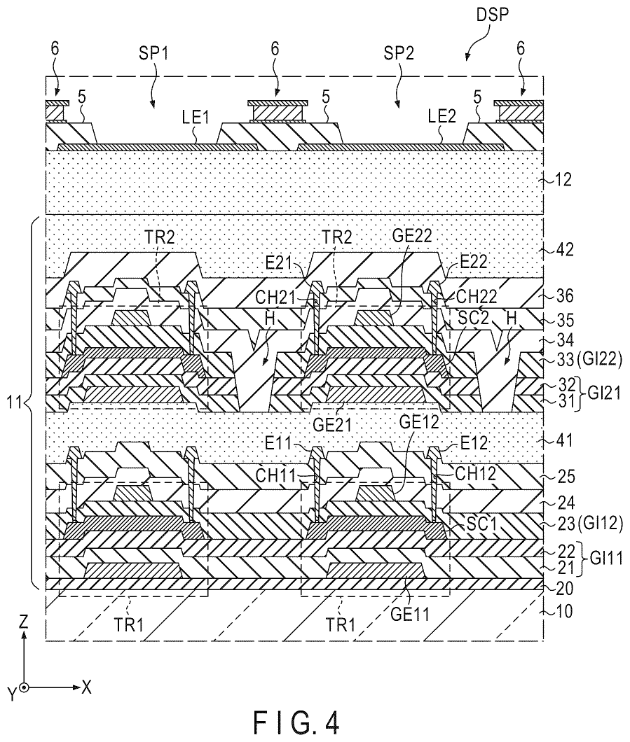

FIG. 4 is a schematic cross-sectional view showing a configuration applicable to a circuit layer 11. This figure omits the stacked films FL1, FL2, and FL3, the sealing layers SE11, SE12, and SE13, the resin layer RS1, the sealing layer SE2, and the resin layer RS2.

The circuit layer 11 has the thin-film transistors TR1 and TR2 shown in FIG. 1. For example, among the two thin-film transistors TR1 and the two thin-film transistors TR2 shown in the figure, the thin-film transistors TR1 and TR2 on the left side constitute the pixel circuit 1 of the subpixel SP1, and the thin-film transistors TR1 and TR2 on the right side constitute the pixel circuit 1 of the subpixel SP2. The thin-film transistors TR1 and TR2 of the pixel circuit 1 of the subpixel SP3 may also adopt the same configuration as the thin-film transistors TR1 and TR2 of the pixel circuits 1 of the subpixels SP1 and SP2 shown in the figure.

In the example of FIG. 4, the thin-film transistor TR2 is located above the thin-film transistor TR1. Furthermore, an organic insulating layer 41 is provided between the thin-film transistors TR1 and TR2, and an organic insulating layer 42 is provided between the thin-film transistor TR2 and the organic insulating layer 12. For example, the bottom surface of the organic insulating layer 12 contacts the upper surface of the organic insulating layer 42. In the same manner as the organic insulating layer 12, the organic insulating layers 41 and 42 each can be formed of an organic insulating material such as a polyimide.

The thin-film transistors TR1 and TR2 need not be arranged in the Z-direction. That is, the thin-film transistors TR1 and TR2 may be shifted with respect to each other in the X-direction or the Y-direction.

Inorganic insulating layers 20, 21, 22, 23, 24, and 25 are sequentially provided in the Z-direction between the substrate 10 and the organic insulating layer 41. These inorganic insulating layers each are formed of an inorganic insulating material such as a silicon nitride, a silicon oxide, or a silicon oxynitride. In one example, the inorganic insulating layers 21 and 24 each are formed of a silicon nitride, and the inorganic insulating layers 20, 22, and 25 each are formed of a silicon oxide.

The thin-film transistor TR1 comprises a semiconductor layer SC1 located between the inorganic insulating layers 22 and 23. The semiconductor layer SC1 may be formed of, for example, an oxide semiconductor (OS). The semiconductor layer SC1 may be formed of a low-temperature polycrystalline silicon (LTPS) or an amorphous silicon.

The thin-film transistor TR1 comprises a gate electrode GE11 located between the semiconductor layer SC1 and the substrate 10, and a gate electrode GE12 located between the semiconductor layer SC1 and the organic insulating layer 41. The gate electrodes GE11 and GE12 face the semiconductor layer SC1. In the example of FIG. 4, the gate electrode GE11 is located between the inorganic insulating layers 20 and 21, and the gate electrode GE12 is located between the inorganic insulating layers 23 and 24. The gate electrodes GE11 and GE12 have, for example, a single-layer structure or a stacked structure of a metal material.

A pair of electrodes E11 and E12 respectively corresponding to a source electrode and a drain electrode are connected to the semiconductor layer SC1. These electrodes E11 and E12 are provided on the inorganic insulating layer 25 and each contact the semiconductor layer SC1 through contact holes CH11 and CH12 each penetrating the inorganic insulating layers 23, 24, and 25.

The inorganic insulating layers 21 and 22 correspond to a gate insulating layer GI11 insulating the semiconductor layer SC1 from the gate electrode GE11. That is, in the example of FIG. 4, the gate insulating layer GI11 includes a plurality of insulating layers. The inorganic insulating layer 23 corresponds to a gate insulating layer GI12 insulating the semiconductor layer SC1 from the gate electrode GE12. The gate insulating layer GI11 may be constituted by a single insulating layer. Further, the gate insulating layer GI12 may be constituted by a plurality of insulating layers.

Inorganic insulating layers 31, 32, 33, 34, 35, and 36 are sequentially provided in the Z-direction between the organic insulating layers 41 and 42. These inorganic insulating layers each are formed of an inorganic insulating material such as a silicon nitride, a silicon oxide, or a silicon oxynitride. In one example, the inorganic insulating layers 31, 34, and 36 each are formed of a silicon nitride, and the inorganic insulating layers 32, 33, and 35 each are formed of a silicon oxide.

The thin-film transistor TR2 comprises a semiconductor layer SC2 located between the inorganic insulating layers 32 and 33. The semiconductor layer SC2 may be formed of, for example, an oxide semiconductor. The semiconductor layer SC2 may be formed of a low-temperature polycrystalline silicon or an amorphous silicon.

The thin-film transistor TR2 comprises a gate electrode GE21 (the first gate electrode) located between the semiconductor layer SC2 and the organic insulating layer 41, and a gate electrode GE22 (the second gate electrode) located between the semiconductor layer SC2 and the inorganic insulating layer 34. The gate electrodes GE21 and GE22 face the semiconductor layer SC2. In the example of FIG. 4, the gate electrode GE21 is located between the organic insulating layer 41 and the inorganic insulating layer 31, and the gate electrode GE22 is located between the inorganic insulating layers 33 and 34. The gate electrodes GE21 and GE22 have, for example, a single-layer structure or a stacked structure of a metal material.

A pair of electrodes E21 and E22 respectively corresponding to a source electrode and a drain electrode are connected to the semiconductor layer SC2. These electrodes E21 and E22 are provided on the inorganic insulating layer 35 and each contact the semiconductor layer SC2 through contact holes CH21 and CH22 each penetrating the inorganic insulating layers 33, 34, and 35.

The inorganic insulating layer 36 covers the electrodes E21 and E22 and the inorganic insulating layer 35. The organic insulating layer 42 covers the inorganic insulating layer 36.

The inorganic insulating layers 31 and 32 correspond to a gate insulating layer GI21 (the first gate insulating layer) insulating the semiconductor layer SC2 from the gate electrode GE21. That is, in the example of FIG. 4, the gate insulating layer GI21 includes a plurality of insulating layers. The inorganic insulating layer 33 corresponds to a gate insulating layer GI22 (the second gate insulating layer) insulating the semiconductor layer SC2 from the gate electrode GE22. The gate insulating layer GI21 may be constituted by a single insulating layer. Further, the gate insulating layer GI22 may be constituted by a plurality of insulating layers.

The gate insulating layers GI21 and GI22 have a plurality of through-holes H reaching the organic insulating layer 41. These through-holes H are closed by the inorganic insulating layer 34. From another viewpoint, at least part of the through-hole H is filled with the inorganic insulating layer 34. The inorganic insulating layer 34 contacts the organic insulating layer 41 through the through-hole H.

For example, the through-hole H is provided between adjacent thin-film transistors TR2. In the example of FIG. 4, at least part of the through-hole H overlaps the rib layer 5 and the partition 6 in the Z-direction.

The planar shape of the through-hole H is not particularly limited. In one example, the through-hole H may have a slit shape extending in a longitudinal direction between adjacent thin-film transistors TR2. In another example, one or more through-holes H may be arranged between adjacent thin-film transistors TR2. For example, the through-hole H in this case may have any of various shapes such as a circular shape, an elliptical shape, a square shape, or a rectangular shape.

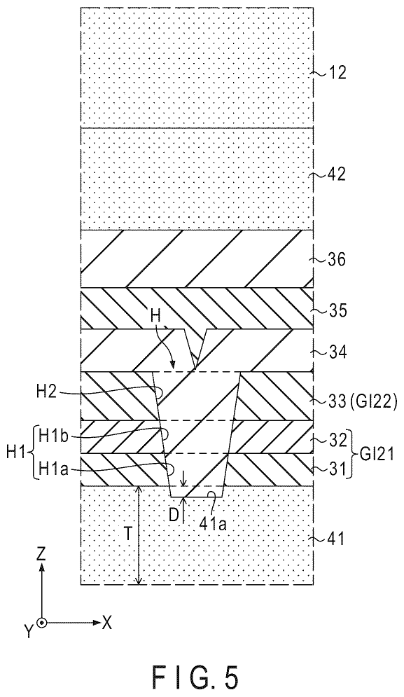

FIG. 5 is a schematic cross-sectional view showing an area in the vicinity of the through-hole H in an enlarged manner. The through-hole H includes a through-hole H1 (the first through-hole) penetrating the gate insulating layer GI21 and a through-hole H2 (the second through-hole) penetrating the gate insulating layer GI22. More specifically, the through-hole H1 includes a through-hole H1a penetrating the inorganic insulating layer 31 and the through-hole H1b penetrating the inorganic insulating layer 32. The through-holes H1a, H1b, and H2 overlap each other in the Z-direction.

The organic insulating layer 41 may have a recess portion 41a overlapping the through-hole H. In the example of FIG. 5, the recess portion 41a is formed in a part exposed from the inorganic insulating layers 31, 32, and 33 of the upper surface of the organic insulating layer 41.

For example, a depth D of the recess portion 41a is 10% or less of a thickness T of the organic insulating layer 41. Here, the depth D corresponds to the maximum depth of the recess portion 41a. For example, the thickness T is 1 to 5 μm, and the depth D is 50 to 200 nm. For example, the thickness T is equal to or less than the thickness of the organic insulating layers 12 and 42.

In the example of FIG. 5, the inorganic insulating layer 34 fills insides of the through-holes H1a, H1b, and H2 and contacts the upper surface of the organic insulating layer 41 (the inner surface of the recess portion 41a). The inorganic insulating layer 34 is formed such that the organic insulating layer 41 is not exposed through the through-hole H. The inorganic insulating layer 34 need not fill at least part of the through-holes H1a, H1b, and H2.

A step corresponding to the through-hole H may be formed on the inorganic insulating layer 34. This step is flattened by the inorganic insulating layers 35 and 36 and the organic insulating layers 12 and 42.

Next, the following will describe a manufacturing method of the display device DSP.

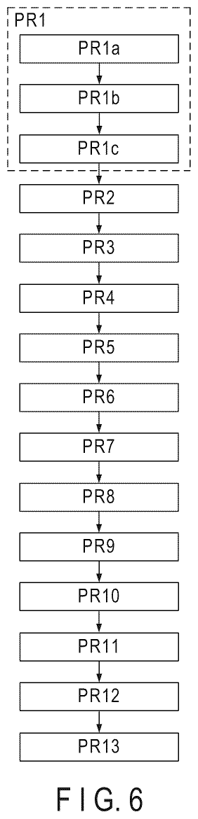

FIG. 6 is a flowchart showing an example of a manufacturing method of the display device DSP of the present embodiment. In the formation of the display device DSP, first, the circuit layer 11 is formed on a mother substrate including areas corresponding to the plurality of display devices DSP (the process PR1).

In the process PR1, first, a lower layer of the circuit layer 11, that is, the inorganic insulating layers 20, 21, 22, 23, 24, and 25, the semiconductor layer SC1, the gate electrodes GE11 and GE12, and the electrodes E11 and E12 are formed (the process PR1a). Next, the organic insulating layer 12 is formed (the process PR1b). Further, the upper layer of the circuit layer 11, that is, the inorganic insulating layers 31, 32, 33, 34, 35, and 36, the organic insulating layer 42, the semiconductor layer SC2, the gate electrodes GE21 and GE22, and the electrodes E21 and E22 are formed (the process PR1c). From another viewpoint, the process PR1a includes a process of forming the thin-film transistor TR1, and the process PR1c includes a process of forming the thin-film transistor TR2.

After the formation of the circuit layer 11, the organic insulating layer 12 is formed (the process PR2). Further, the lower electrodes LE1, LE2, and LE3 are formed (the process PR3), followed by the formation of a rib layer 5 covering these lower electrodes LE1, LE2, and LE3 (the process PR4). At this time, the pixel apertures AP1, AP2, and AP3 are not provided in the rib layer 5.

After the formation of the rib layer 5, the partition 6 is formed (the process PR5). Furthermore, the pixel apertures AP1, AP2, and AP3 are formed in the rib layer 5 (the process PR6). The pixel apertures AP1, AP2, and AP3 may be formed before the formation of the partition 6.

Next, the display element DE1 is formed (the process PR7). In the process PR7, first, the organic layer OR1, the cap layer CP1, the upper electrode UE1, and the sealing layer SE11 are formed on the entire mother substrate. Furthermore, except for the parts located in the subpixel SP1, the organic layer OR1, the cap layer CP1, the upper electrode UE1, and the sealing layer SE11 are removed.

After the formation of the display element DE1, the display element DE2 is formed (the process PR8). Thereafter, the display element DE3 is formed (the process PR9). These processes PR8 and PR9 are the same as the process PR7 of forming the display element DE1.

Subsequently, the resin layer RS1 is formed (the process PR10), the sealing layer SE2 covering the resin layer RS1 is formed (the process PR11), and the resin layer RS2 covering the sealing layer SE2 is formed (the process PR12). Further, parts corresponding to the display devices DSP are cut out from the mother substrate (the process PR13). The display device DSP is completed through at least these processes.

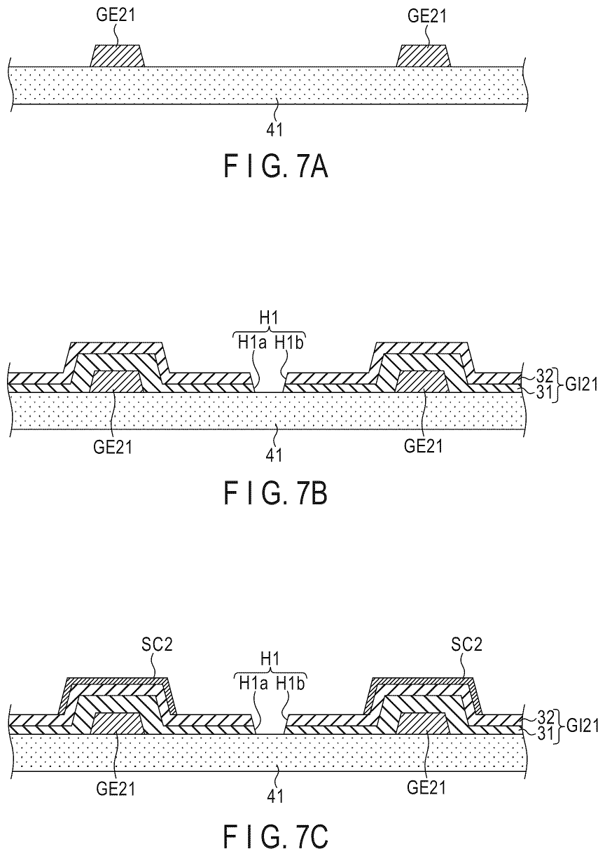

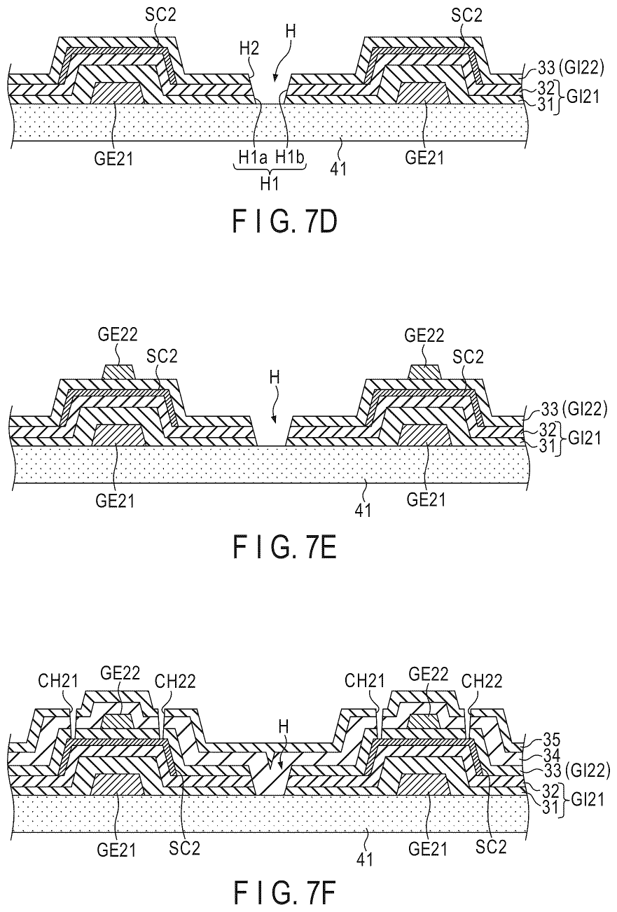

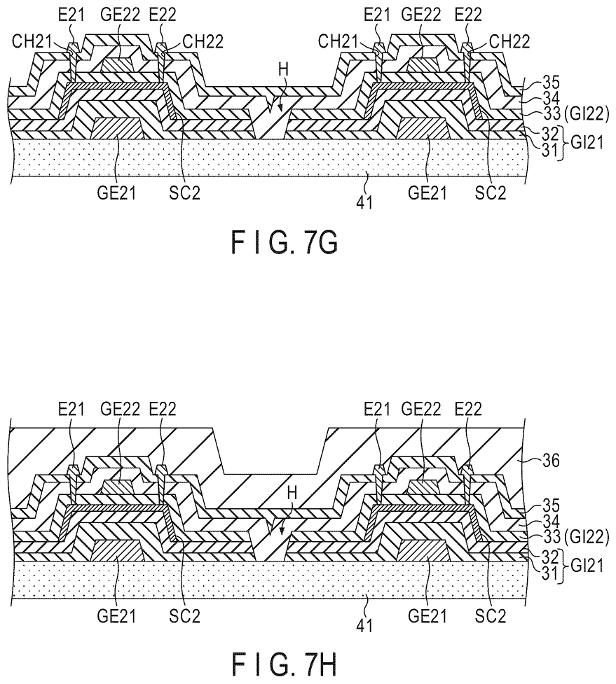

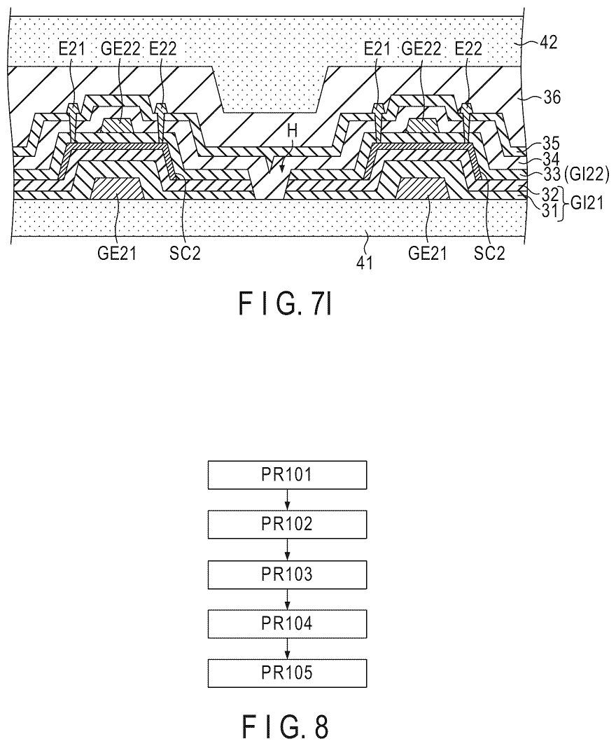

FIG. 7A to FIG. 7I are schematic cross-sectional views showing manufacturing processes included in the process PR1c of FIG. 6. FIG. 7A to FIG. 7I mainly focus on parts of the display area DA and omit the illustration of elements under the organic insulating layer 41.

In the process PR1c, first, as shown in FIG. 7A, the gate electrode GE21 is formed on the organic insulating layer 41. Subsequently, as shown in FIG. 7B, inorganic insulating layers 31 and 32 (the gate insulating layer GI21) covering the gate electrode GE21 are formed. Further, the through-holes H1a and H1b (the through-holes H1) are formed in the respective inorganic insulating layers 31 and 32.

Next, as shown in FIG. 7C, the semiconductor layer SC2 is formed on the inorganic insulating layer 32. Subsequently, as shown in FIG. 7D, the inorganic insulating layer 33 (the gate insulating layer GI22) covering the semiconductor layer SC2 is formed. Further, the through-hole H2 is formed in the inorganic insulating layer 33. The through-hole H2 and the through-holes H1a and H1b constitute the through-hole H.

Next, the gate electrode GE22 is formed as shown in FIG. 7E. Further, doping is performed on the semiconductor layer SC2 using the gate electrode GE22 as a mask.

Thereafter, as shown in FIG. 7F, the inorganic insulating layers 34 and 35 covering the gate electrode GE22 are formed. Further, the contact holes CH21 and CH22 are formed in the inorganic insulating layers 34 and 35. The through-hole H is blocked by the inorganic insulating layer 34. Before formation of the inorganic insulating layer 34, the process of heating the mother substrate is performed (the process PR101 in FIG. 8). This process will be described later in detail.

Next, as shown in FIG. 7G, the electrodes E21 and E22 that contact the semiconductor layer SC2 through the contact holes CH21 and CH22 are formed. Further, as shown in FIG. 7H, the inorganic insulating layer 36 that covers the inorganic insulating layer 35 and the electrodes E21 and E22 is formed. Further, as shown in FIG. 7I, the organic insulating layer 42 covering the inorganic insulating layer 36 is formed.

FIG. 8 is a flowchart showing a process flow for forming inorganic insulating layers such as the inorganic insulating layers 31, 32, 33, 34, 35, and 36. In forming the inorganic insulating layer, preheating of the mother substrate is first performed (the process PR101). Next, an inorganic insulating layer is formed on the mother substrate by CVD (Chemical Vapor Deposition).

Subsequently, a resist for processing the inorganic insulating layer is provided (the process PR103). Thereafter, the dry etching using the resist as a mask is performed (the process PR104). This dry etching patterns the inorganic insulating layer. After the dry etching, the resist is removed (the process PR105).

The recess portion 41a shown in FIG. 5 can be formed by dry etching during formation of the inorganic insulating layers 31, 32, and 33 and the gate electrode GE22, or by ashing during removal of the resist. That is, when these dry etching processes and the ashing are performed under conditions that can erode the material of the organic insulating layer 41, the upper surface of the organic insulating layer 41 is eroded through the through-holes H1a, H1b, and H2. These processes form the recess portion 41a corresponding to the shape of the through-hole H.

Next, the following will describe effects of the present embodiment.

In the present embodiment, the thin film transistors TR1 and TR2 included in the pixel circuit 1 of each subpixel SP are arranged in two layers, namely the lower layer (the part between the substrate 10 and the organic insulating layer 41) and the upper layer (the part between the organic insulating layers 41 and 42). This configuration enables higher definition of the display area DA as compared with a configuration in which the thin film transistors TR1 and TR2 are provided in the same layer.

In the present embodiment, the organic insulating layer 41 is provided between the thin film transistors TR1 and TR2. This configuration reduces a step caused by the thin film transistor TR1 in the lower layer, thus suppresses a shape defect of the thin film transistor TR2 in the upper layer.

However, in general, the heat resistance temperature of the organic insulating layer 41 is lower than that of the inorganic insulating layer. Thus, heat generated during formation of the respective elements of the thin film transistor TR2 may cause bubbles or peeling at the interface between the organic insulating layer 41 and the inorganic insulating layer, and may cause wrinkles due to thermal shrinkage of the organic insulating layer 41.

The through-hole H formed in the inorganic insulating layers 31, 32, and 33 can suppress such bubbles and peeling. In other words, with the through-hole H formed as shown in FIG. 7E, execution of the preheating process PR101 for forming the inorganic insulating layer 34 discharges moisture and gas of the organic insulating layer 41 through the through-hole H. This configuration suppresses generation of bubbles caused by the organic insulating layer 41 and stripping of the organic insulating layer 41 in various heating processes performed after the through-hole H is closed by the inorganic insulating layer 34. Thus, the yield of the display device DSP can be improved.

From the viewpoint of suitably suppressing the occurrence of bubbles and peeling, the preheating for forming the inorganic insulating layers 31, 32, 33, and 34 preferably proceeds in a vacuum or nitrogen atmosphere for about 5 to 60 minutes, for example, at a temperature of 100 °C or higher, or at a temperature higher than the deposition temperature of the inorganic insulating layers 31, 32, and 33 and not higher than the heat resistance temperatures of the organic insulating layer 41 and the thin-film transistor TR1.

In the manufacturing method of FIG. 7A to FIG. 7I, the through-holes H1a and H1b are formed during the formation of the inorganic insulating layers 31 and 32 (FIG. 7B). This formation enables discharge of moisture and the like in the organic insulating layer 41 through the through-holes H1a and H1b even by heat during formation of the semiconductor layer SC2, the inorganic insulating layer 33, and the gate electrode GE22.

The processes for forming the inorganic insulating layers 31, 32, and 33, the semiconductor layer SC2, and the gate electrode GE22 may include a process of cleaning the mother substrate after removal of a resist used for patterning thereof. Moisture may enter the organic insulating layer 41 also during this cleaning. This moisture is discharged as appropriate through the through-holes H1a, H1b, and H2 by heating during formation of the respective layers. After the inorganic insulating layer 34 closes the through-hole H, suppression of moisture intrusion into the organic insulating layer 41 is achieved even when similar cleaning is performed.

The method of forming the through-hole H is not limited to the example of FIG. 7A to FIG. 7I. As another example, the through-hole H may be formed by dry etching for the inorganic insulating layers 31, 32, and 33, after formation of these inorganic insulating layers 31, 32, and 33.

The pixel circuit 1 may comprise three or more thin-film transistors. In this case, no particular limitation applies to whether each thin-film transistor is provided in the upper layer or the lower layer of the circuit layer 11. The configuration of each thin-film transistor is not necessarily limited to the configuration comprising the two gate electrodes as in the thin-film transistors TR1 and TR2 of the present embodiment.

The present embodiment discloses the display device DSP having the configuration in which the partition 6 separates the organic layer, the upper electrode, and the cap layer. Alternatively, the display device DSP may omit the partition 6 and adopt a configuration in which the organic layer, the upper electrode, and the cap layer extend continuously across the plurality of subpixels SP. As described above, the configuration of the circuit layer 11 disclosed in the present embodiment is also applicable to display devices including display elements other than organic electroluminescence elements.

All of the display devices and manufacturing methods thereof that can be implemented by a person of ordinary skill in the art through arbitrary design changes to the display device and manufacturing method thereof disclosed above as the embodiment of the present invention come within the scope of the present invention as long as they are in keeping with the spirit of the present invention.

Various types of the modified examples are easily conceivable within the category of the ideas of the present invention by a person of ordinary skill in the art and the modified examples are also considered to fall within the scope of the present invention. For example, additions, deletions or changes in design of the constituent elements or additions, omissions, or changes in condition of the processes arbitrarily conducted by a person of ordinary skill in the art, in the above embodiments, fall within the scope of the present invention as long as they are in keeping with the spirit of the present invention.

In addition, the other advantages of the aspects described in the embodiments, which are obvious from the descriptions of the present specification or which can be arbitrarily conceived by a person of ordinary skill in the art, are considered to be achievable by the present invention as a matter of course.

What is claimed is

1. A display device, comprising:
a first thin-film transistor;
an organic insulating layer located above the first thin-film transistor;
a second thin-film transistor located above the organic insulating layer and comprising a semiconductor layer, a gate electrode facing the semiconductor layer, and a gate insulating layer located between the semiconductor layer and the gate electrode;
an inorganic insulating layer located above the second thin-film transistor; and
a display element located above the inorganic insulating layer and driven by a pixel circuit including the first thin-film transistor and the second thin-film transistor, wherein
the gate insulating layer includes a through-hole reaching the organic insulating layer, and
the inorganic insulating layer closes the through-hole.

2. The display device of claim 1, wherein
the gate electrode includes:
a first gate electrode located between the organic insulating layer and the semiconductor layer; and
a second gate electrode located between the semiconductor layer and the inorganic insulating layer,
the gate insulating layer includes:
a first gate insulating layer located between the semiconductor layer and the first gate electrode; and
a second gate insulating layer located between the semiconductor layer and the second gate electrode, and
the through-hole includes:
a first through-hole penetrating the first gate insulating layer; and
a second through-hole penetrating the second gate insulating layer and overlapping the first through-hole.

3. The display device of claim 2, wherein
the first gate insulating layer includes a plurality of insulating layers each formed of an inorganic insulating material, and
the first through-hole penetrates each of the plurality of insulating layers.

4. The display device of claim 1, wherein
the organic insulating layer has a recess portion overlapping the through-hole.

5. The display device of claim 4, wherein
a depth of the recess portion is 10% or less of a thickness of the organic insulating layer.

6. The display device of claim 1, wherein
the inorganic insulating layer contacts the organic insulating layer through the through-hole.

7. The display device of claim 1, wherein
the inorganic insulating layer is formed of a silicon nitride.

8. The display device of claim 1, wherein
the second thin-film transistor further comprises an electrode contacting the semiconductor layer through a contact hole penetrating the inorganic insulating layer.

9. The display device of claim 1, wherein
the display element comprises:
a first electrode connected to the pixel circuit;
a second electrode facing the first electrode; and
an organic layer located between the first electrode and the second electrode and emitting light in response to voltage application.

10. The display device of claim 9, further comprising:
a rib layer covering an end portion of the first electrode and having a pixel aperture overlapping the first electrode; and
a partition provided above the rib layer and having an overhang shape.

11. A display device manufacturing method, comprising:
forming a first thin-film transistor;
forming an organic insulating layer above the first thin-film transistor;
forming, above the organic insulating layer, a second thin-film transistor including a semiconductor layer, a gate electrode facing the semiconductor layer, and a gate insulating layer located between the semiconductor layer and the gate electrode and having a through-hole reaching the organic insulating layer;
heating a substrate on which the first thin-film transistor, the organic insulating layer, and the second thin-film transistor are formed;
forming, after the heating, an inorganic insulating layer located above the second thin-film transistor and closing the through-hole; and
forming, above the inorganic insulating layer, a display element driven by a pixel circuit including the first thin-film transistor and the second thin-film transistor.

12. The manufacturing method of claim 11, wherein
the gate electrode includes a first gate electrode and a second gate electrode,
the gate insulating layer includes a first gate insulating layer and a second gate insulating layer, and
the forming of the second thin-film transistor includes:
forming the first gate electrode above the organic insulating layer;
forming the first gate insulating layer covering the first gate electrode and the organic insulating layer and having a first through-hole reaching the organic insulating layer;
forming the semiconductor layer above the first gate insulating layer;
forming the second gate insulating layer covering the semiconductor layer and having a second through-hole overlapping the first through-hole; and
forming the second gate electrode above the second gate insulating layer.

13. The manufacturing method of claim 12, wherein
the first gate insulating layer includes a plurality of insulating layers each formed of an inorganic insulating material, and
the first through-hole penetrates each of the plurality of insulating layers.

14. The manufacturing method of claim 12, wherein
at least one of etching for the forming of the second gate insulating layer and etching for the forming of the second gate electrode forms a recess portion overlapping the through-hole in the organic insulating layer.

15. The manufacturing method of claim 14, wherein
a depth of the recess portion is 10% or less of a thickness of the organic insulating layer.

16. The manufacturing method of claim 11, wherein
the inorganic insulating layer contacts the organic insulating layer through the through-hole.

17. The manufacturing method of claim 11, wherein
the inorganic insulating layer is formed of a silicon nitride.

18. The manufacturing method of claim 11, further comprising:
forming a contact hole penetrating the inorganic insulating layer; and
forming an electrode contacting the semiconductor layer through the contact hole.

19. The manufacturing method of claim 11, wherein
the display element further comprises:
a first electrode connected to the pixel circuit;
a second electrode facing the first electrode; and
an organic layer located between the first electrode and the second electrode and emitting light in response to voltage application.

20. The manufacturing method of claim 19, further comprising:
forming a rib layer covering an end portion of the first electrode and having a pixel aperture overlapping the first electrode; and
forming a partition having an overhang shape above the rib layer.
